(19) United States
(12) Patent Application Publication
(10) Pub. No.: US 2002/0145847 A1
(43) Pub. Date: Oct. 10, 2002

(54) Portable computer

(76) Inventor: Catherine K. Crosby, Alexandria, VA (US)

Correspondence Address: CATHERINE K. CROSBY, 4926-C EISENHOWER AVENUE, ALEXANDRIA, VA, 22304, US

(21) Appl. No.: 09/824,718

(22) Filed: Apr. 4, 2001

(51) Int. Cl. G06F 1/16; H05K 5/00

(52) U.S. Cl. 361/683

(57) ABSTRACT

A portable, lightweight, robust computer composed of a monitor/keyboard module and a CPU module which can be separated from each other and selectively recombined is presented. Both modules individually and jointly can fit into most overhead compartments on today's major airlines, and the combined unit can easily be secured in and removed from a standard bay in a nineteen inch rack-mount cabinet. A dual track system allows the portable computer to be compact yet able to provide for the uncomplicated insertion and removal of six standard commercial off-the-shelf computer data storage devices. The monitor/keyboard module includes a detachable keyboard and touchpad mouse which can be repositioned as the user desires, and it includes a monitor which is manually rotatable from an upright position to a compact position in which it covers the keyboard. The monitor can be locked in its compact position to ensure safe transport of the monitor/keyboard module and to prevent anyone from easily typing or from viewing the monitor while the user is absent. Power and data communications cables are removably attached to a connector panel located on one side of the CPU module so that common computer data storage devices may be connected and disconnected exteriorly to the CPU module.

### BACKGROUND OF THE INVENTION

1. Field of the Invention

The present invention relates generally to electronic information equipment and more specifically to a portable computer having a novel monitor/keyboard module and a novel CPU module.

2. Description of the Related Art

Numerous apparatuses have been devised for providing portable computers with adjustable keyboard and display units. Some of the most significant advances in the art have centered around the development of computers having modular, configurable subcomponents. However, none of the references herein described presents a portable computer including a monitor and keyboard module reversibly attachable to a separate CPU module in which the internal layout of the CPU housing is specially arranged so as to provide sufficient room for the placement of a sliding track assembly system for holding up to six computer data storage devices therein. For example, U.S. Pat. No. 4,718,740, issued to Cox, presents a housing and stowage mechanism for a terminal keyboard and data display. This invention includes a rectangular housing mounted vertically on a wall having a front face hinged along the lower edge for opening to a horizontal position. A keyboard is mounted on the upper portion of the housing face interiorly of the housing, and a display panel is pivotally suspended from the lower edge of the keyboard. U.S. Pat. No. 4,832,419, issued to Mitchell et al., discloses a mechanism for adjusting the height and viewing angle of a flat panel display which is viewed in conjunction with a portable personal computer. The mechanism includes a pair of arms that swing the display panel between the lowered and raised position, cooperating with a cam wheel moveable in a cam track.

U.S. Pat. No. 4,851,812, issued to Holmberg, discloses a portable data system which includes a bottom plate and a lid. The bottom plate carriers a PC-computer having a keyboard and a pivotal presentation screen which in its lowered position forms part of the upper surface of the computer. The system also includes a voltage source for powering the computer and the screen. Two parallel-arm mechanisms arranged on each side of the computer enable a carrier plate with printer to move away from the computer and partially into a raised lid.

U.S. Pat. No. 4,980,676, issued to Nomura et. al., discusses an electronic apparatus with keyboard, including a portable personal computer in which the keyboard can be stored in a case in an upright position in such a manner that it is surface mounted with the keys facing toward the inside.

U.S. Pat. No. 5,034,858, issued to Kawamoto et al., discloses a computer assembly constructed to accommodate a keyboard sandwiched between a main body and a display. The keyboard is provided separably from the main body. The display is attached to the main body by a supporting device at a position where the display face is movable to a predetermined position.

U.S. Pat. No. 5,646,820, issued to Honda et al., discusses a portable computer having a box-like case with a front wall and an upper wall continuous with the front wall. A keyboard is arranged on the upper wall of the case, and a display unit is supported by the case. The display unit is rotatable between a first position wherein the display unit covers the keyboard and a second position wherein the display unit exposes the keyboard.

U.S. Pat. No. 5,706,167, issued to Lee, discusses a portable notebook computer having an ergonomically designed keyboard made up of two rotatably separable keyboard sections. Upon opening up the lid of the notebook computer, the user may manually rotate the keyboard sections apart to a desired angle.

U.S. Design Pat. No. 306,433, issued to Mitchell, shows a laptop computer. U.S. Design Pat. No. 294,029, issued to Nishiyama et al., illustrates a portable computer. And finally, U.S. Design Pat. No. 317,302, issued to Shibuya et al., illustrates a portable computer.

None of the above inventions and patents, taken either singularly or in combination, is seen to describe the instant invention as claimed. Thus, a portable computer with modular assemblies, including a novel monitor/keyboard module and a novel CPU module solving the aforementioned problems is desired.

### SUMMARY OF THE INVENTION

The principal object of the present invention includes a portable computer which is comprised of a CPU module and a monitor/keyboard module which can be separated from and then recombined with the CPU module. The monitor/keyboard module is detachably connected to the CPU module by means of tabs which extend rearwardly from its base and engage slots located on one side panel of the CPU module, and is secured by thumb screws located at the front corners of monitor/keyboard module which engage threaded holes located on the aforementioned side panel of the CPU module.

The monitor/keyboard module can be mounted to the CPU module in two discrete configurations. This feature allows the user the freedom to decide which position suits his needs best. An innovation of the invention is that the portable computer fits into a “6U” bay in an industry-standard nineteen inch rack-mount cabinet when the monitor/keyboard module is attached to the CPU module in the same direction as the data storage drives so that the monitor, keyboard, and data storage drives are easily assessable from the front side of the rack-mount cabinet. This invention presents a unique solution to a long felt need in that there are at present no computer servers or workstations that can be used at the desktop, in a rack-mount cabinet, and then transported with ease on today's airlines.

In order for the portable computer to be easily transportable, the monitor/keyboard module as well as the CPU module must be lightweight, sturdy, and compact. Both modules may be compactly stored for transport, e.g., in knapsack or other carry-on luggage, and either separably or jointly can fit into most overhead compartments on today's common airlines.

Yet still another object of the invention is to provide a monitor/keyboard module that can be used with any standard PC workstation or server. The monitor/keyboard module principally includes a thin flat panel LCD, an AC adapter used to provide power to the LCD, and a keyboard with serial and PS2 connectors. The keyboard may include a touchpad mouse.

The keyboard with touchpad mouse can be detached from and then recombined with the monitor/keyboard module so that the user can reposition the keyboard with touchpad in any desired way.

Additionally, it should be understood that the keyboard with touchpad mouse can be ported to and used by any other computer system that requires a similar keyboard and mouse.

Yet still another object of the invention is to provide a monitor/keyboard module which includes a cable storage compartment and a disk drive storage compartment.

Yet still another object of the invention is to provide a monitor/keyboard module which includes a monitor which is manually rotatable from an upright position to a compact position in which it covers the keyboard. The two points of rotation allow the monitor to frictionally rotate anywhere between 0 and 270 degrees from its compact/portable position. The monitor arm has a locking device which serves two purposes: (1) secure transport of the monitor/keyboard module in compact form, and (2) while the computer system is running a program, the user can lock the monitor arm so that no one can easily type on the keyboard or view the contents on the monitor.

The invention provides an important advantage in that the internal layout of its associated CPU module is designed to provide for the maximum efficient utilization of space, allowing for an open architecture design which allows user-friendly upgrades and the uncomplicated insertion and removal of standard commercial off-the-shelf personal computer components. Because one side panel can easily be removed and reattached, the main circuit board, cpu, system memory, computer expansion cards, power supply, and any other computer components internal to the CPU module can easily be upgraded by the end-user as desired.

A critically important part of the invention includes a dual track system which allows the portable computer to be compact yet able to provide for the uncomplicated insertion and removal of a plurality of standard commercial off-the-shelf computer data storage devices. Pairs of mirrored flanges form tracks which are stacked vertically in two separate columns to form an array of bays called the dual track system. The user attaches each computer data storage drive to a pair of rails, thereafter slidably inserting the resulting combination through mating tracks. Computer data storage drives can be secured in and removed from the tracks of the dual track system without using a screwdriver. Furthermore, the mirrored flanges which form the tracks contribute to the overall strength of the CPU module and permit the dual track system to be made of a very thin and lightweight metal.

Yet it is still another object of the invention to provide a CPU module in which the internal ambient air remains at or near room temperature during operation. Ventilation holes and fans strategically placed within the CPU module help to accomplish this task.

Power cables and data communications cables for IDE (Integrated Drive Electronics) and SCSI (Small Computer System Interface) computer data storage devices are removably attached to a connector panel located on one side of the CPU module so that common IDE and SCSI computer data storage devices may be connected and disconnected from the CPU module without opening any exterior side panels of the CPU module. The power and data communications cables may also be used to supply power and data communications to the optional disk drive housed in the monitor/keyboard module.

The modular architecture of the portable computer would permit: (1) the user to travel from a home base carrying with him the CPU module with or without the monitor/keyboard module, (2) attach the CPU module to a compatible monitor/keyboard module at his destination, (3) use power and data communications cables to transfer data between data storage drives located inside and outside the CPU module, (4) disconnect and detach monitor/keyboard module from the CPU module, and (5) transport CPU module back to his home base. Capabilities of step three may be extended to include the ability to be used in extracting, copying, and imaging data as well as searching, retrieving, and sorting data from many types of existing computer data storage.

Yet still another object of the invention is to provide CPU module which houses a removable hard drive tray which is accessible from the side of the CPU module opposing the dual track system. Two common 2.5″ notebook hard drives or one common 3.5″ hard drive can be removably installed in this hard drive tray.

It is an object of the invention to provide improved elements and arrangement thereof for the purposes described which is inexpensive, dependable and fully effective in accomplishing its intended purposes.

These and other objects, features, aspects and advantages of the present invention will become readily apparent upon further review of the following specifications and drawings.

### BRIEF DESCRIPTION OF THE DRAWINGS

The accompanying drawings illustrate a preferred embodiment of the invention, and together with the general description given above and the detailed description given below, serve to explain the principles of the invention.

FIG. 1A is a front angular perspective view of the monitor/keyboard module in a state wherein the monitor is pivoted to a ninety degree position.

FIG. 1B is a back angular perspective view of the monitor/keyboard module in a state wherein the monitor is pivoted to a ninety degree position.

FIG. 1C is a second back angular perspective view of the monitor/keyboard module in a state wherein the monitor is pivoted to a ninety degree position.

FIG. 2 is a top view of the monitor/keyboard module showing the monitor/keyboard module according to the invention with the upper wall of the housing removed.

FIG. 3 is a diagrammatic side view of the monitor/keyboard module according to the invention with a side wall removed.

FIG. 3A is a detailed configuration view of the apparatus which secures the monitor to the monitor/keyboard module.

FIG. 4 is a top view of a second embodiment of the monitor/keyboard module with the keyboard detached from the module.

FIG. 4A is a side view of a FIG. 4 with the keyboard secured in the base of the module.

FIG. 5 is a perspective view of the monitor/keyboard module attached to the CPU module to form a portable PC according to the invention which is ready for transport.

FIG. 6A is a perspective view of a portable computer according to the invention.

FIG. 6B is a perspective view of a portable computer according to the invention.

FIG. 6C is a perspective view of a portable computer according to the invention which is ready to be rack-mounted.

FIG. 7 is a perspective view of a dual track system for mounting disk drives in a portable computer according to the invention.

FIG. 8 is a second perspective view of a dual track system for mounting disk drives in a portable computer according to the invention.

FIG. 9 is a perspective view of a decorative cover which removably attaches to the front side of the dual track system according to the invention.

FIG. 10 is a perspective view of a connector panel and cables according to the invention.

FIG. 11A is a side perspective view of the CPU module according to the invention.

FIG. 11B is detailed side view of the removable input/output bracket according to the invention.

FIG. 11C is a detailed side view of the removable power supply mounting bracket according to the invention.

FIG. 12 is a perspective view of a removable hard drive tray according to the invention.

FIG. 13 is a schematic drawing of the internal layout of the CPU module of a portable computer according to the invention.

Similar reference characters denote corresponding features consistently throughout the attached drawings.

### DETAILED DESCRIPTION OF THE PREFERRED EMBODIMENTS

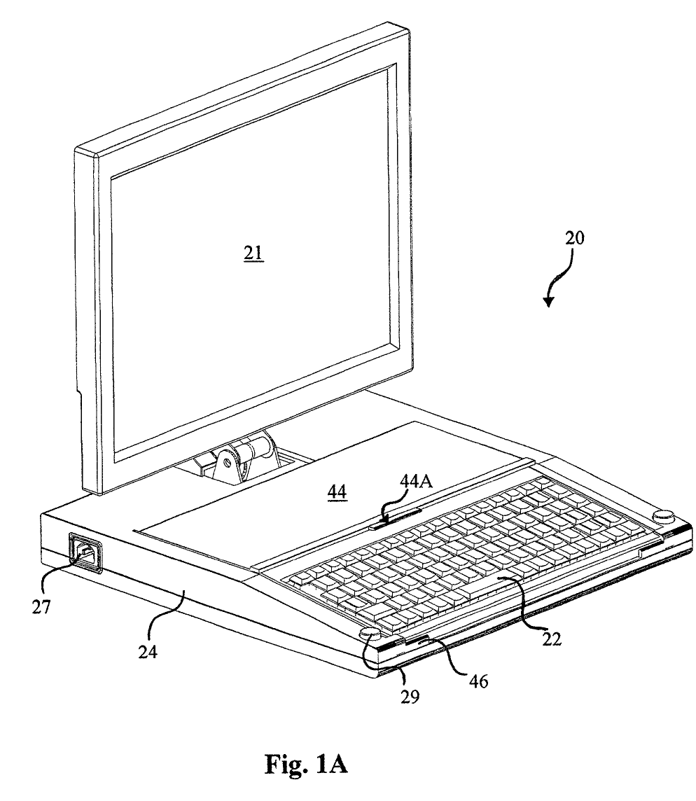

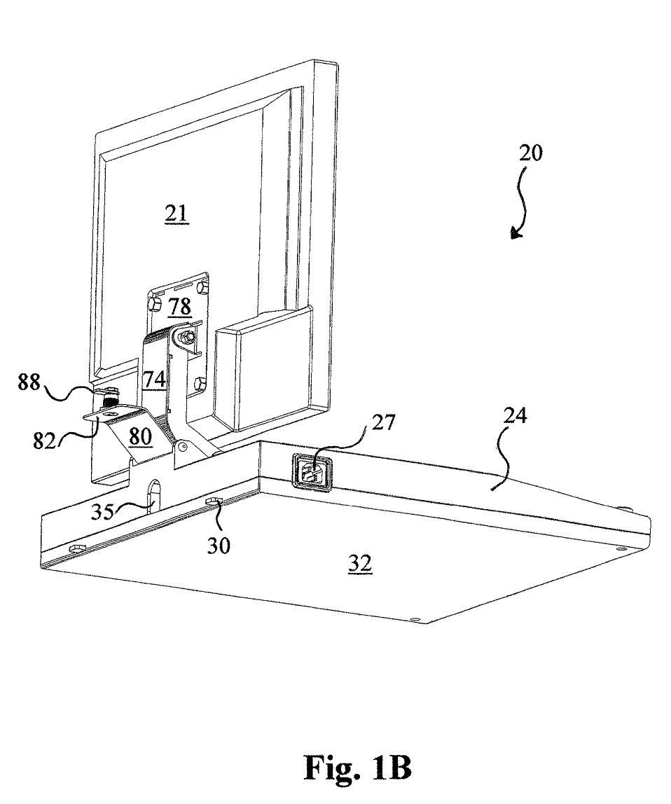

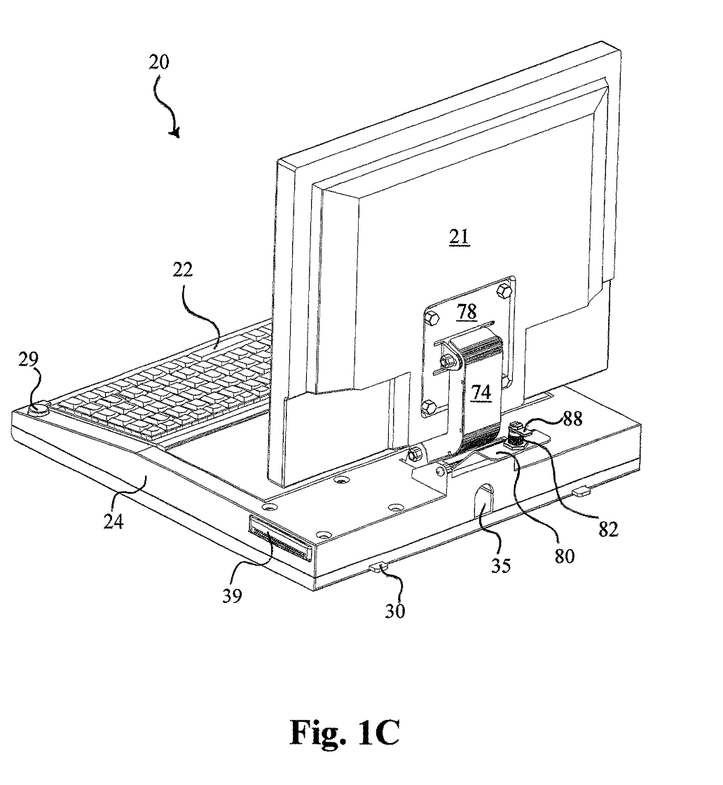

The present invention is directed to a portable computer having a monitor/keyboard module and a CPU module, the monitor/keyboard module being detachably connected to the CPU module. The preferred embodiment of the invention is depicted in FIGS. 1-13 and is generally referenced by the numeral 10.

Referring now generally to the drawings and more particularly to FIGS. 1A-1C, it can be seen that the monitor/keyboard module 20 principally includes a thin flat panel LCD (Liquid Crystal Display) monitor 21, keyboard 22, and module base 24 for a portable desktop computer that can be separated from, and then recombined with, either the same or a different CPU module 100 so that the monitor/keyboard module 20 may be compactly stored for transport, e.g., in a knapsack or other carry-on luggage during airline travel, and connected to the same or a different CPU module 100 at the traveler's destination.

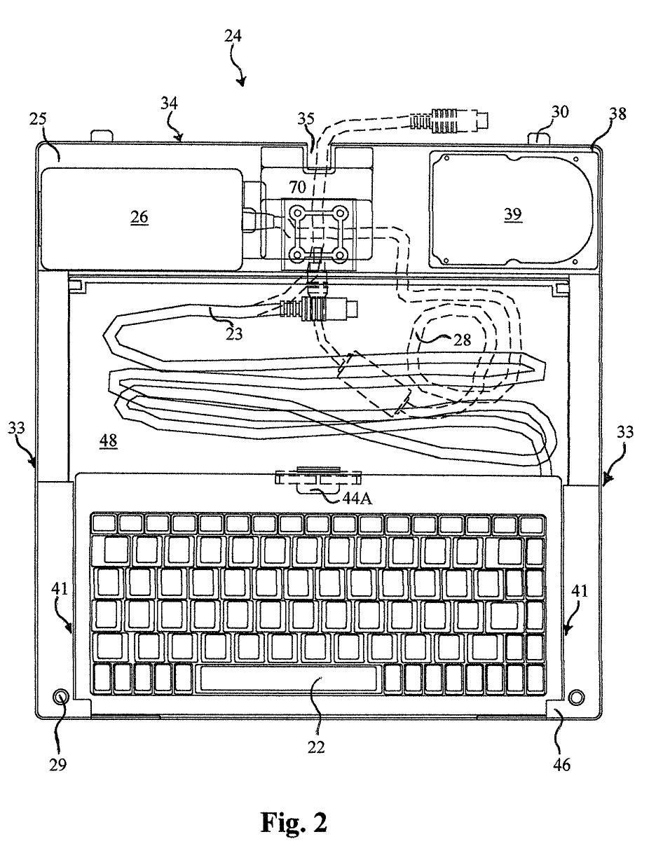

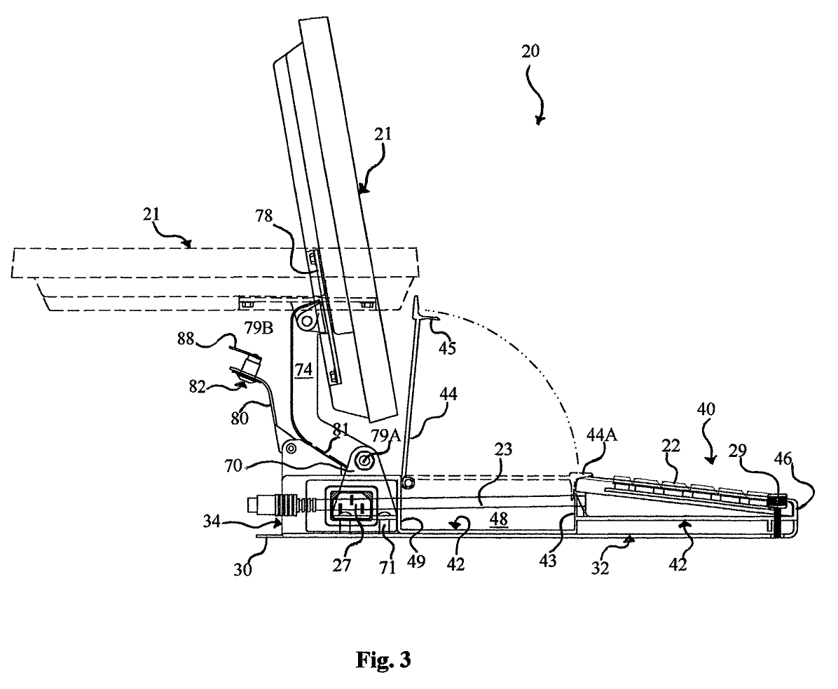

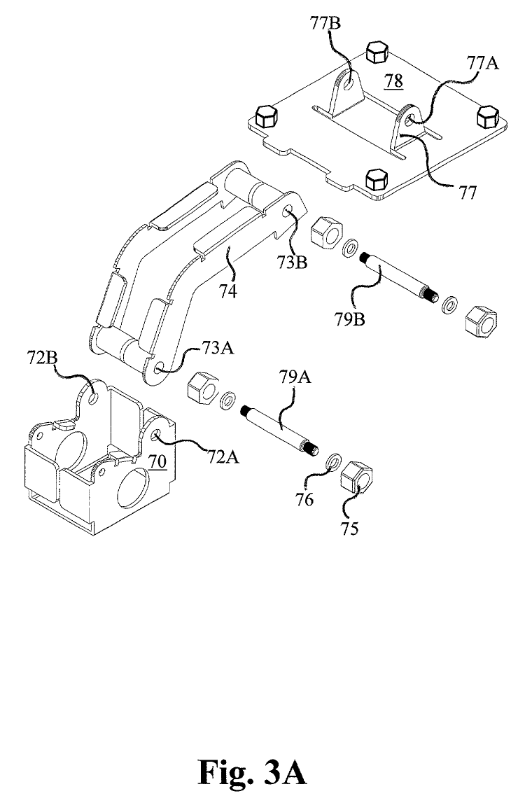

In the preferred embodiment, the module base 24 is made from a plastic material and defines a plurality of compartments, as shown in FIG. 2. FIG. 2 shows base 24 with the top of the base housing removed to show the internal layout of base 24. As depicted in FIGS. 2 and 3, the module base 24 has a flat horizontal bottom wall 32, side walls 33, a rear wall 34, and a pair of keyboard retainer tabs 46 at the front corners of the base 24. Divider walls define a keyboard compartment 40 towards the front of the base 24, a user assessable cable storage compartment 48 in the rear of the keyboard compartment 40, a disk drive storage compartment 38 for an optional disk drive 39, a storage compartment 25 for AC adapter 26 which supplies power to the monitor 21.

The keyboard compartment 40 is defined by divider sidewalls 41, an inner divider wall 42 which runs parallel to bottom wall 32, and a central retaining tab 43 which sticks out perpendicular to inner divider wall 42. The compartment 40 is dimensioned for receiving an elevated keyboard 22. The keyboard cable 23 is normally disposed in cable storage compartment 48 for safe and secure storage and/or transport of the monitor/keyboard module 20. Cable storage compartment 48 has sufficient room to store AC adapter cable 28, a video cable for connecting the monitor 21 to the CPU module, a power cord for connecting the AC adapter 26 to an electrical outlet, and a power cord for connecting the power supply 146 of CPU module 100 to an electrical outlet. The keyboard cable 23 extends within compartment 48 and through a hole in divider wall 49 which runs perpendicular to inner divider wall 42, then the keyboard cable 23 continues through a narrow passageway within the monitor support structure 70 and may be pulled out through port 35 in the center of rear wall 34 of base 24 for connection to the CPU module 100. In preparation for storage and transport of the monitor/keyboard module 20, the keyboard cable 23 can be retracted through port 35 and the hole in divider wall 49 by pulling on the keyboard cable 23 from within storage compartment 48.

The keyboard 22 may be removably installed in keyboard compartment 40 by sliding the front edge of the keyboard 22 against keyboard retainer tabs 46 and releasing the back edge of the keyboard so that it rests in front of the central retaining tab 43. The keyboard is retained in the keyboard compartment 40 by the retainer tabs 46 in conjunction with a cable storage compartment cover 44 which rotates between an open position for access to the cable storage compartment 48 and a closed position shown in phantom in FIG. 3. Cable storage compartment cover 44 has a depending flange 45 which engages central retaining tab 43 in a snap fastener fashion to retain the cover 44 in the closed position, and a lip and tab 44A which overlays the rear of the keyboard 22 to retain the keyboard 22 in compartment 40.

Disk drive storage compartment 38 is provided so that an optional disk drive 39 may be housed in the base module 24. AC adapter 26 is provided for supplying power to the monitor 21. A three prong connector 27 is available on a sidewall 33 of base 24 for receiving a power cord to connect the AC adapter 26 to an electrical outlet. Referring to FIG. 2, AC adapter cable 28 is pre-installed so that it extends between four standoffs 71 which attach the monitor support structure 70 to bottom wall 32, and then through a hole in divider wall 49 so that the majority of the length of AC adapter cable 28 can be stored within the user accessible cable storage compartment 48. From within compartment 48, AC adapter cable 28 follows the same passageway as the keyboard cable 23. AC adapter cable 28 extends within compartment 48 and through a hole in divider wall 49 which runs perpendicular to inner divider wall 42, then it continues through a narrow passageway within the monitor support structure 70 and may be pulled out through port 35 in the center of rear wall 34 of base 24 for connection to the monitor 21. In preparation for storage and transport of the monitor/keyboard module 20, AC adapter cable 28 can be retracted through port 35 and the hole in divider wall 49 by pulling on cable 28 from within storage compartment 48.

Referring to FIGS. 3 and 3A, the monitor arm 74 pivotally rotates around shaft 79A. Shaft 79A passes through hole 72A in monitor support structure 70, through cylinder 73A in the lower portion of monitor arm 74, and out through opposing hole 72B at the other side of the monitor support structure 70. The monitor arm 74 is then secured to the monitor support structure 70 by locknuts 75. The monitor mounting bracket 78, attached to the back of the monitor 21 by four screws, similarly rotates around shaft 79B attached to the upper portion of monitor arm 74. Shaft 79B passes through hole 77A in flange 77, through cylinder 73B in the upper portion of monitor arm 74, and passes out through hole 77B. Lock washers 76 placed around shaft 79A and between the locknuts 75 and the monitor support structure 70, and between the monitor arm 74 and the monitor support structure 70, provide frictional motion at this pivot point. Lock washers are similarly used at shaft 79B for the same purpose. The two points of rotation 79A and 79B allow the monitor 21 to frictionally rotate anywhere between 0 and 270 degrees from its compact/portable position.

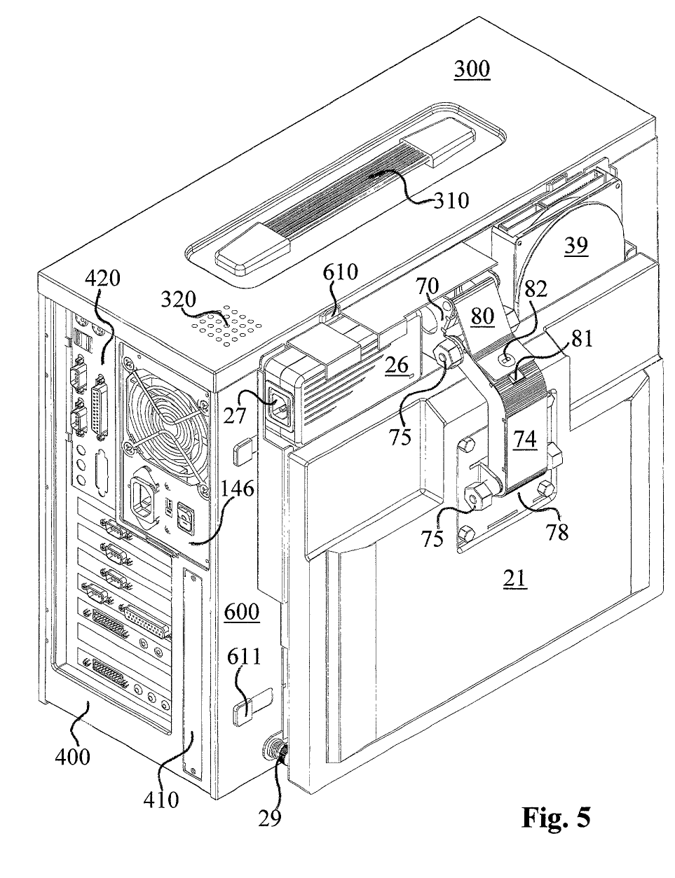

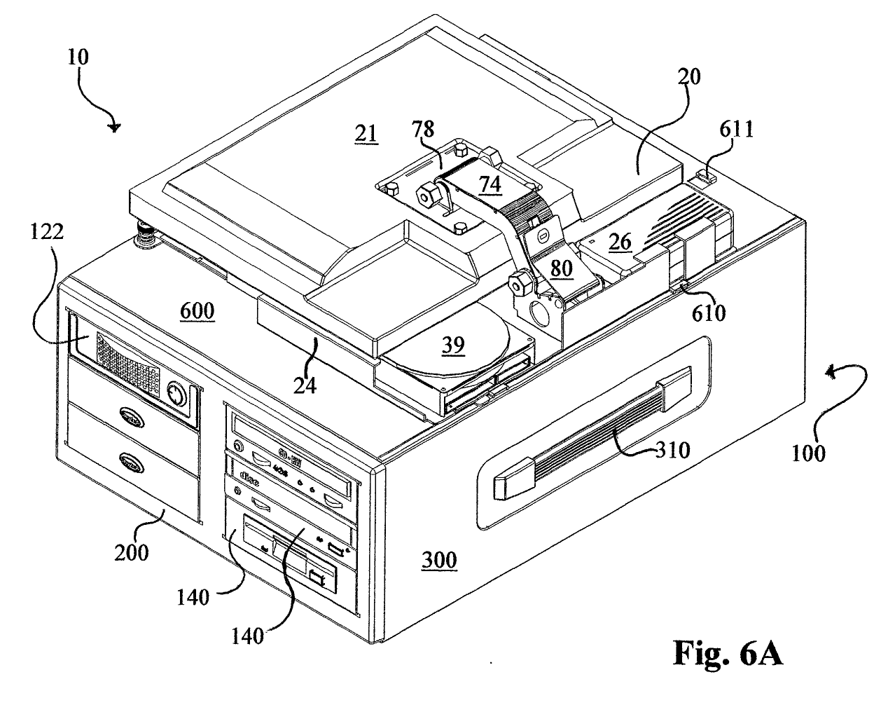

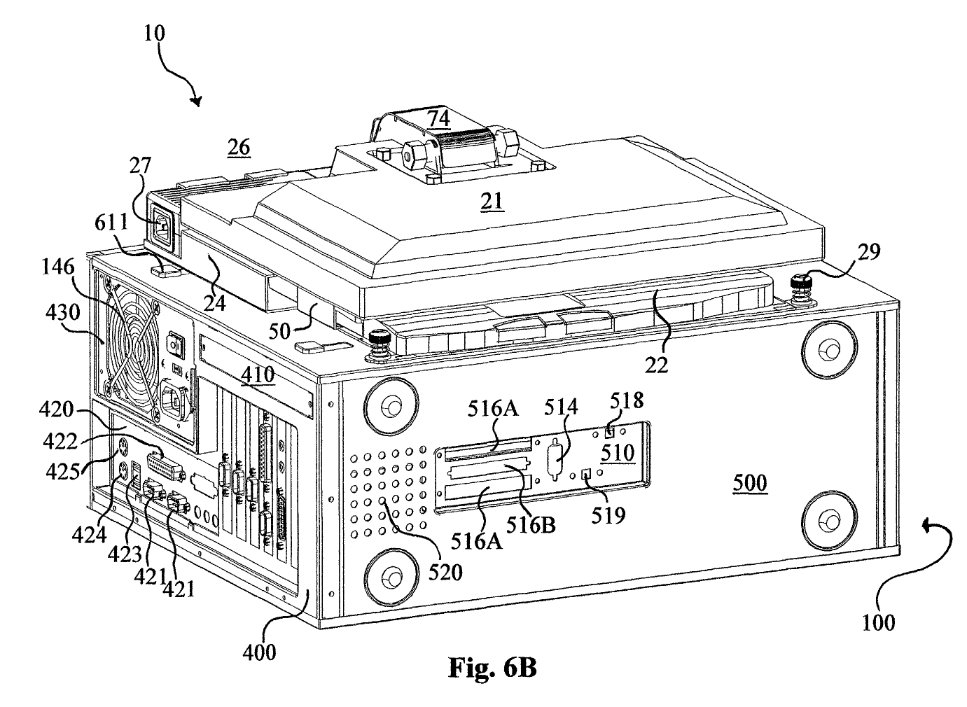

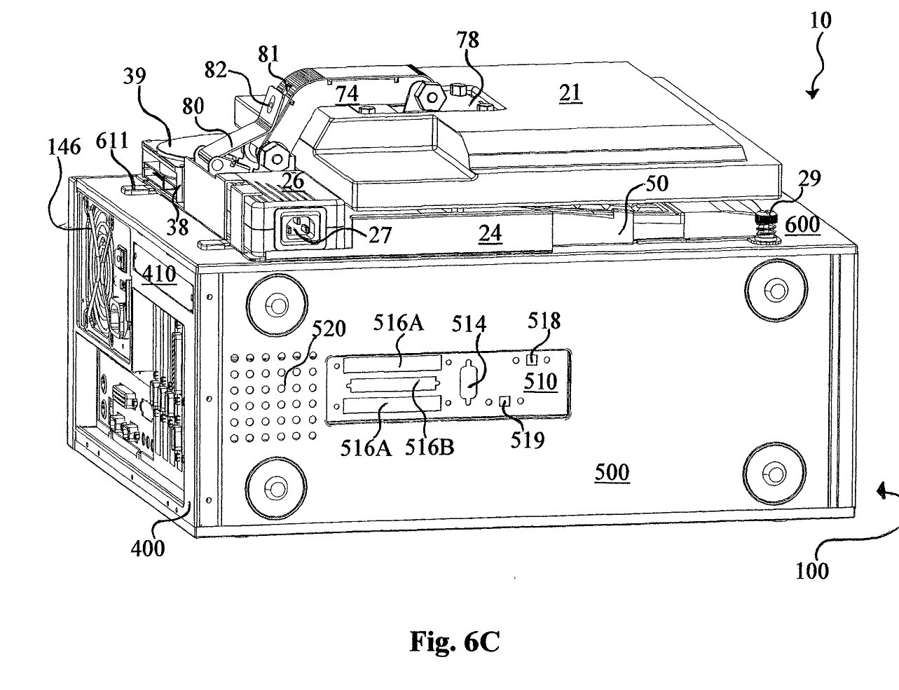

The locking device 82 for monitor arm 74 provides for two important purposes: (1) secure transport of the monitor/keyboard module 20 in compact form, as seen in FIGS. 5-6C, and (2) while the computer system is running a program, the user can lock the monitor arm 74 so that no one can easily type on the keyboard 22 or view the contents on the monitor 21. With the monitor screen 21 forward and into compact configuration as shown in FIGS. 5-6C wherein the monitor 21 covers the keyboard 22, the lock arm 80 which is pivotally mounted to the rear of the monitor support structure 70 may be rotated until it closely abuts against the monitor support arm 74. Lock arm 80 which supports the locking device 82 at the free end thereof is rotated forward until the locking device 82 with its locking member 88 is disposed into an aperture 81 in the monitor support arm 74. The lock arm 80 closely abuts against the monitor support arm 74 once the locking device 82 is disposed into the aperture 81. The locking device 82 with its locking member 88 may be selectively key actuated to lockingly engage the monitor support arm 74 so that the monitor 21 remains in its compact form.

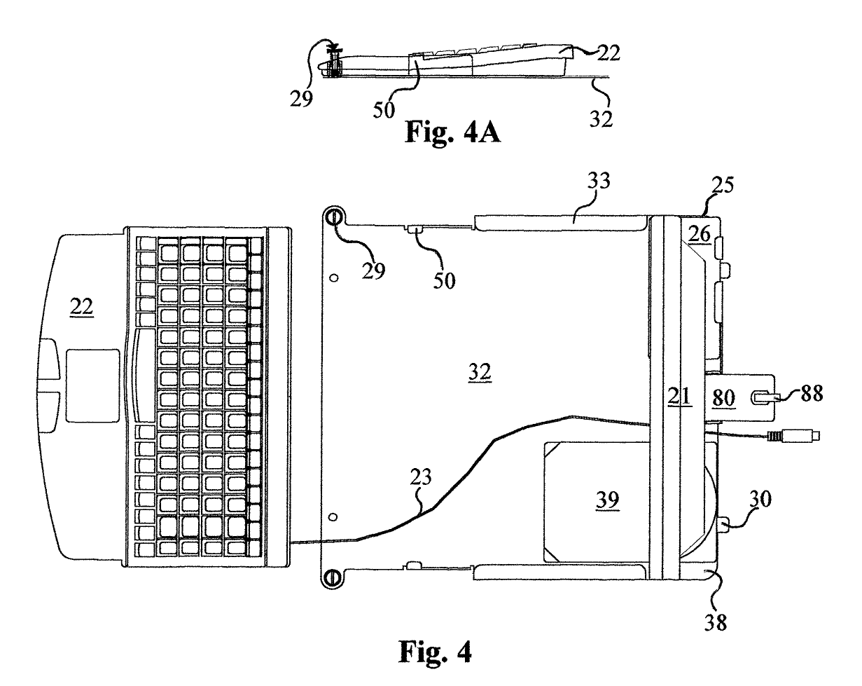

Turning now to FIG. 4, a less preferred embodiment of the monitor/keyboard module 20 is displayed. In this embodiment, the base 24 is made from metal and has an AC adapter compartment 25 which houses AC adapter 26, a keyboard compartment 40 which houses keyboard 22, and a disk drive compartment 38 which houses a removable external hard disk drive 39. The top edge of vertical side wall 33 is bent at ninety degrees in order to form a ledge for the monitor to rest when the monitor is folded to its compact and portable position. This ledge also prevents the monitor 21 from touching the keyboard. The base 24 removably attaches to the CPU module 100 by means of tabs 30 which extend rearwardly from the base 24 and engage slots 610 (seen in FIG. 6A) or recessed slots 611 (seen in FIG. 6C) on the CPU module 100 housing, and is secured by thumb screws 29 located at the front corners of base 24 which engage threaded holes located on the removable side panel 600 of the CPU module 100.

FIG. 4 and 4A demonstrate how the keyboard 22 with touchpad mouse can be detached from and then recombined with module base 24, allowing for greater flexibility of use so that the user can reposition the keyboard 22 in any desired way. The keyboard 22 may be removably installed in keyboard compartment 40 by sliding the side edges of the keyboard 22 through retaining walls 50 located on both sides of module base 24. Like keyboard 22, retaining walls 50 are inclined to secure the keyboard in the keyboard compartment 40. The keyboard cable 23 extends through a gap between the disk drive 39 and the monitor support structure 70 for connection to the CPU module 100. Additionally, it should be understood that the keyboard 22 with touchpad mouse can be ported to and used by any other computer system that requires a similar keyboard and mouse. Although this embodiment of the monitor/keyboard module 20 is less attractive aesthetically than the embodiment shown in FIGS. 1-3, it is nevertheless a possible way of carrying out the present invention and is intended to be within the scope of the following claims.

FIGS. 5-6C illustrate the combination of a monitor/keyboard module 20 with a CPU module 100 to form the portable computer 10 of the present invention. The monitor/keyboard module 20 is detachably connected to CPU module 100 by means of tabs 30 which extend rearwardly from the base 24 and engage slots 610 (as shown in FIG. 6A) or recessed slots 611 (as shown in FIG. 6C), and is secured by thumb screws 29 located at the front corners of monitor/keyboard module 20 which engage threaded holes located on the removable side panel 600 of the CPU module 100. Because the monitor/keyboard module 20 can be mounted in two different positions, the user has the freedom to decide which position suits his needs best.

As seen particularly in FIG. 5, wherein the invention is positioned for carry by handle 310, the portable computer 10 forms a compact unit which may be easily transported. The invention provides an important advantage in that the internal structure of its associated CPU module 100 is designed to provide for maximum efficient utilization of the CPU module's internal space, allowing for an open architecture design which allows user-friendly upgrades and the uncomplicated insertion and removal of standard commercial off-the-shelf personal computer components. Because side panel 600 can easily be removed and reattached, the main circuit board 148, cpu, computer expansion cards 144, power supply 146, and other computer components internal to CPU module 100 can easily be changed by the end-user as desired.

The recessed area of side 300 not only helps to provide flush surface or subsurface storage of the handle, but also gives strength to side panel 300 of the CPU module 100 so that a thin and lightweight metal can be used to form this panel. A rib following the same pattern as the recessed area is also placed on side 300 for additional strength.

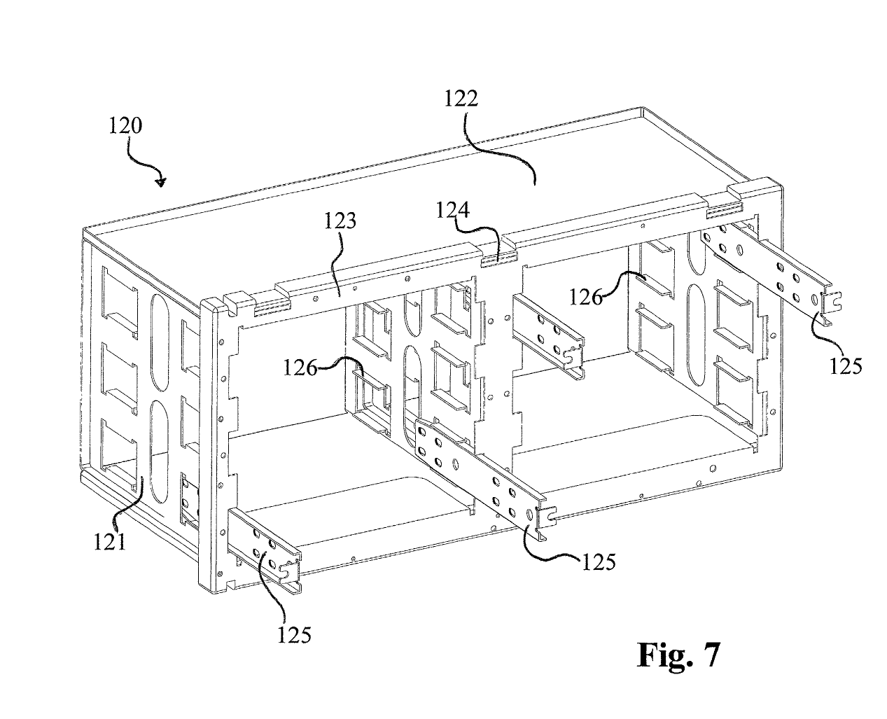

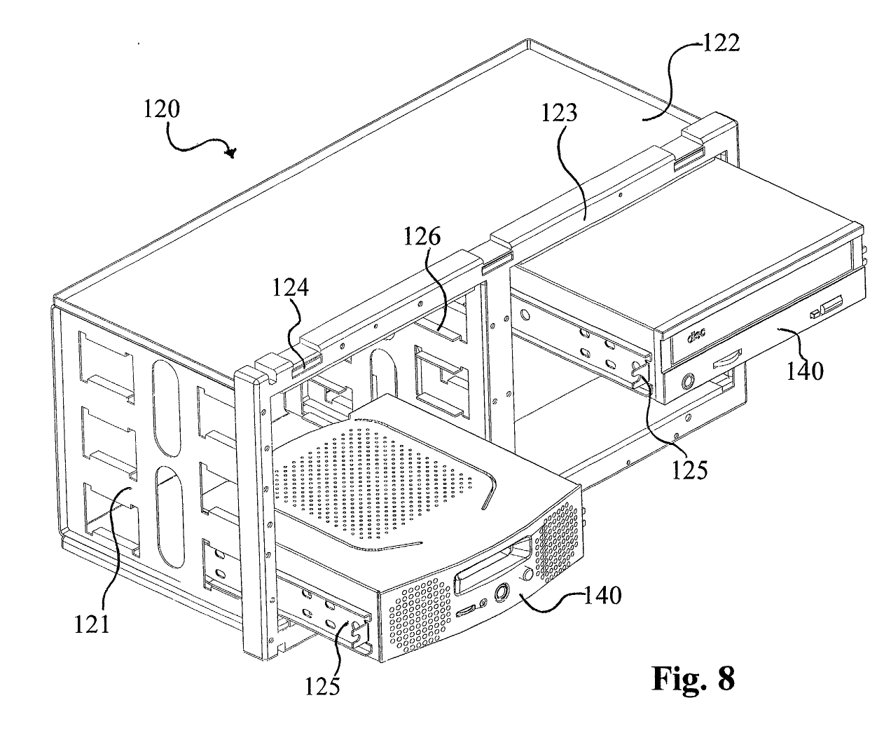

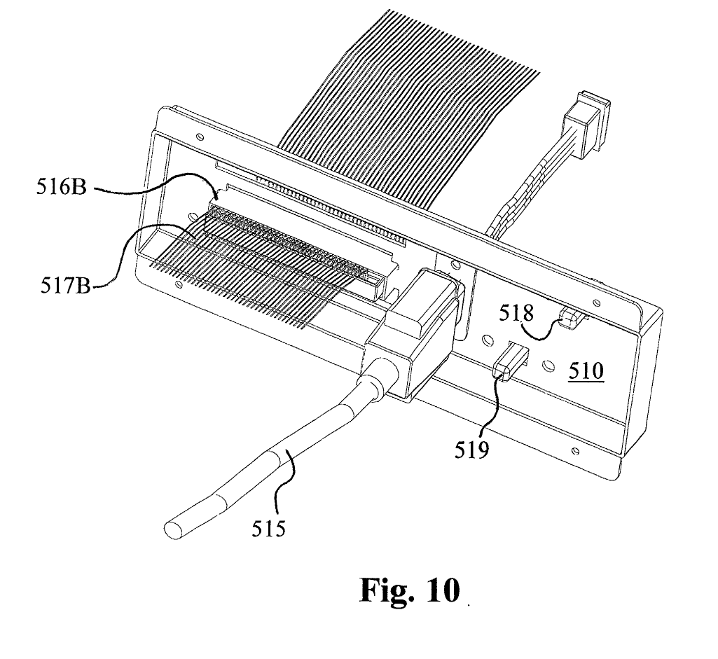

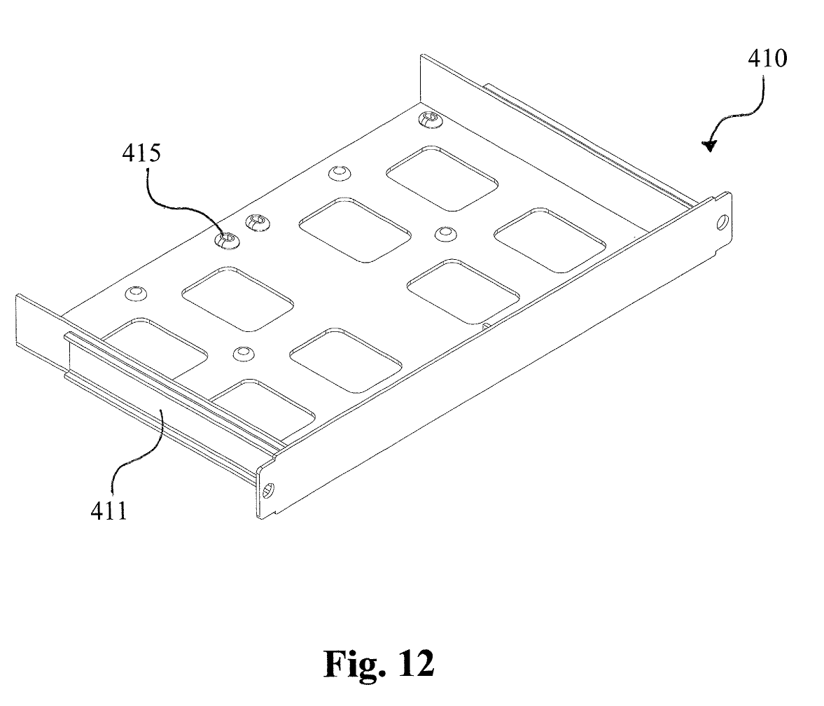

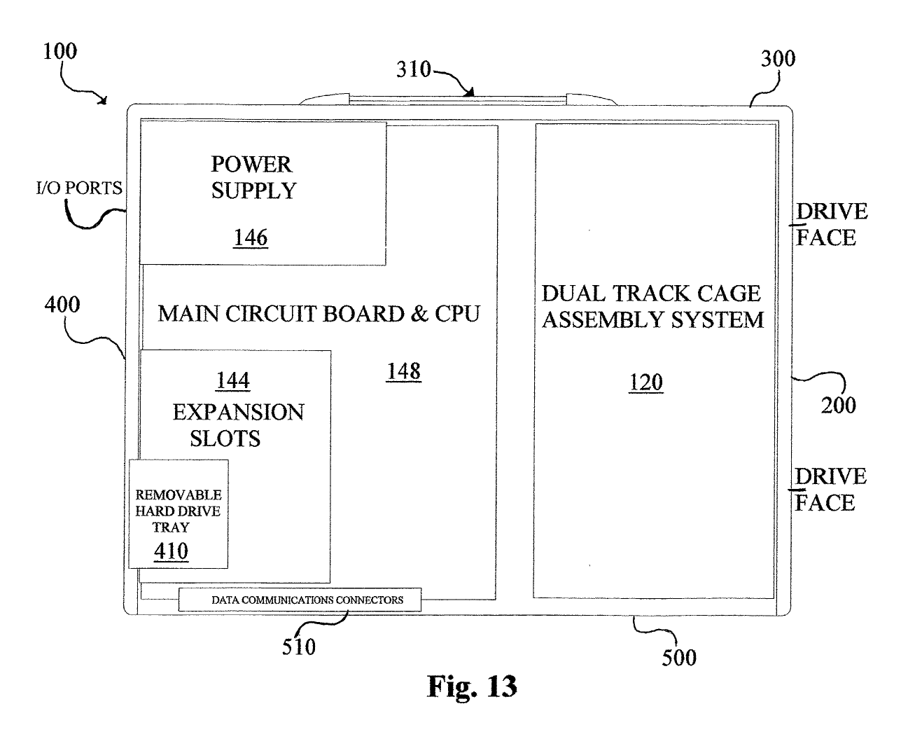

FIG. 13 shows a diagrammatic view of the internal layout of the CPU module 100. Expansion card slots 144, main circuit board 148 with central processing unit and system memory, power supply 146, and removable hard drive tray 410 (close-up view shown in FIG. 12) are mounted toward side 400 of CPU module 100. Data cable connector panel 510 (close-up view shown in FIG. 10) is positioned on side 500 of the CPU module 100, and it houses power connector 514, data cable connectors 516A and 516B, power switch 518, and reset switch 519. The layout of CPU module 100 also permits a dual track cage assembly system 120 (detailed in FIGS. 7 and 8) to be mounted so that computer data storage devices 140 can be easily installed and removed from side 200 of CPU module 100.

Four vertical panels 121 positioned as shown in FIGS. 7 and 8 are connected together by mirrored upper and lower horizontal panels 122 and a front panel 123 with three holes 124. As illustrated in FIGS. 7 and 8, this configuration forms the dual track system 120 which allows the portable computer 10 to be compact yet able to provide for the uncomplicated insertion and removal of six standard commercial off-the-shelf computer data storage devices. Vertical panels 121 with three pairs of mirrored flanges form the tracks 126. The user attaches computer data storage devices, generally 140, to a pair of rails, each 125, thereafter slidably inserting the resulting combination through mating tracks, indicated at 126. Three pairs of tracks are stacked vertically in two separate columns to form an array of six bays called the dual track system 120. The tracks 126 preferably hold six data storage devices 140, namely but not limited to CD-ROMs, DVD-ROM, DVD-RAMs, CDRWs, hard drives, floppy drives, computer card readers within the dual track system 120. Furthermore, the mirrored flanges which form tracks 126 contribute to the overall strength of CPU module 100 and permit the dual track system 120 to be made of a very thin and lightweight metal.

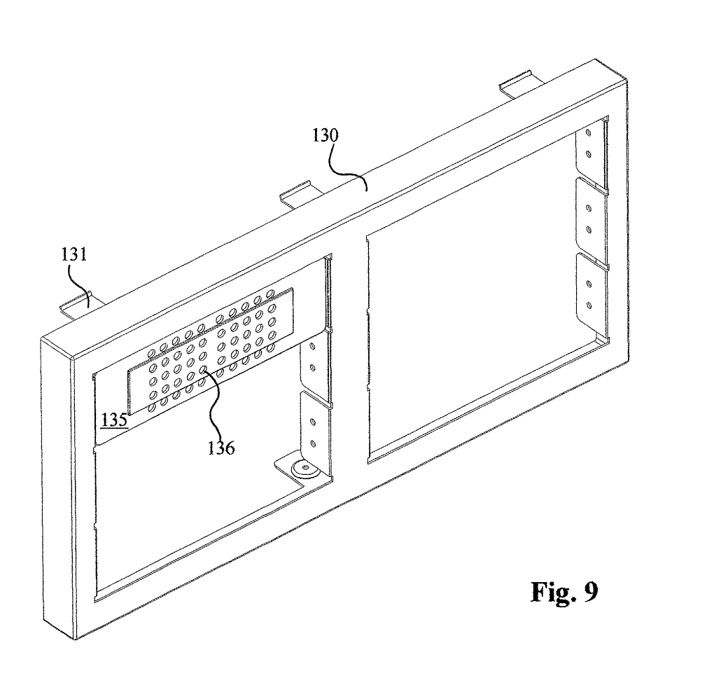

A decorative cover 130 (shown in FIG. 9) is removably attached to the front side of the dual track system 120 at side 200 of CPU module 100. Legs 131 on the upper edge of decorative cover 130 are inserted into holes 124 on front panel 123 of the dual track system 120, and the decorative cover 130 is secured to the side panel opposite to removable side panel 600 with the use of a single thumbscrew. The decorative cover serves three purposes: (1) aesthetics, (2) it keeps the rails 125 and consequentially the computer data storage devices 140 from sliding out of the tracks 126 while the system is transported, and (3) it allows the six computer data storage devices 140 to be secured in and removed from the tracks 126, and consequentially the CPU module 100, without using a screwdriver. U-shaped panels 135 can be easily attached to decorative cover 130 if one or more of the six bays is left unused or if a data storage device 140 does not need to be externally accessible. Air outlet holes 136 are provided on U-shaped panels 135 so that common computer cooling fans can be easily attached in a position opposing holes 136 to extract warm air which may build up inside CPU module 100. To ensure that the central processing unit, system memory, data storage devices 140, and other computer components inside CPU module 100 remain at or below room temperature, a fan is attached at air intake holes 320 to pull cool ambient room air into CPU module 100. Similarly a fan is attached at air outlet holes 520 to extract warm air from inside CPU module 100.

FIG. 10 illustrates an optional data cable connector panel 510 which may be secured to Side 500 of CPU module 100. Power connector 514 and data communications cable connectors 516A for IDE (Integrated Drive Electronics) and 516B for SCSI (Small Computer System Interface) computer data storage devices 140 are positioned on connector panel 510 so that common IDE and SCSI computer data storage devices 140 may be connected and removed externally to the CPU module 100. Long data communications cables 517A and 517B may be connected to the associated data communications cable connectors 516A and 516B, respectively, so that computer data storage devices 140 may be run externally to and at a distance from the CPU module 100. Power cable 515 connected to power connector 514 is needed to supply power to any computer data storage devices 140 connected externally to the CPU module 100. Power cable 515 connected to power connector 514 and data communications cable 517A (or 517B) connected to data communications cable connector 516A (or 516B) may also be used to supply power and data communications for the optional disk drive 39 housed in the monitor/keyboard module 20. Advantageously, the data communication cables 517A and 517B may be proprietary cables.

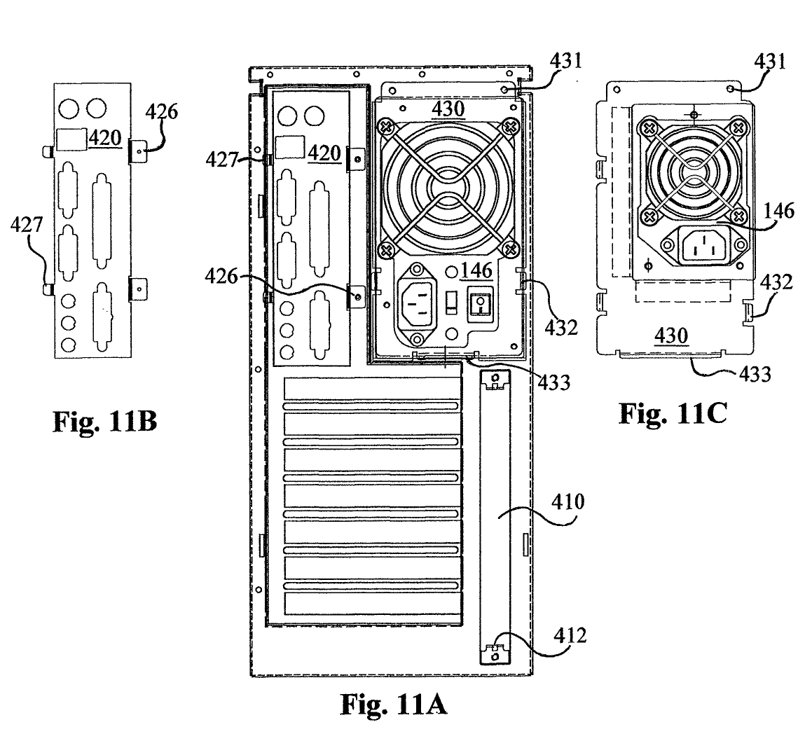

FIGS. 11A-11C show that side 400 of CPU module 100 is comprised of a removable bracket which houses a plurality of input/output connectors, a removable bracket to attach a power supply, and a removable hard drive tray. Additionally the connectors on the back of computer expansion cards can be accessed from this side 400. More particularly, FIG. 11B shows input/output bracket 420 which can house a PS2 keyboard connector, a PS2 mouse connector, two USB (Universal Serial Bus) ports, serial ports, and a parallel port. Two recessed retaining tabs 427 and two screw holes 426 on the input/output bracket 420 allow it to be easily installed and replaced to meet the needs of the main circuit board 148. Similarly power supply bracket 430 shown in FIG. 11C with recessed tabs, 432 and 433, and screw holes 431 can be changed to meet the dimensional requirements of the power supply. A three prong connector on the power supply 146 for receiving a power cord to connect it to an electrical outlet is accessible from this side 400.

FIG. 11A and FIG. 12 show removable hard drive tray 410 which is user accessible from side 400 of CPU module 100. Two common 2.5″ notebook hard drives or one common 3.5″ hard drive can be removably installed in hard drive tray 410. Standoffs positioned on the hard drive tray 410 allow air to circulate under the disk drives which helps to prevent overheating of the hard drives. U-brackets 411 welded to opposing sides of the removable hard drive tray 410 glide along L-brackets 412 during the insertion or removable of the hard drive tray 410 with hard disk drives.

The modular architecture of the portable computer 10 would permit: (1) the user to travel from a home base carrying with him the CPU module 100 with or without the monitor/keyboard module 20, (2) attach the CPU module 100 to a compatible monitor/keyboard module 20 at his destination, (3) use cables 515, 517A, and 517B to supply power and data communications to disk drive 39 and other computer data storage devices 140 connected externally to CPU module 100, (4) transfer contents between data storage devices 140 located inside the CPU module 100, disk drive 39, and external data storage devices 140 connected to data communications cables 517A and 517B, (5) disconnect and detach monitor/keyboard module 20 from the CPU module 100, and (6) transport CPU module 100 back to his home base. Capabilities of step four may be extended to include the ability to be used in extracting, copying, and imaging data as well as searching, retrieving, and sorting data from many types of existing computer data storage.

As previously noted and particularly shown in FIGS. 6B and 6C, the monitor/keyboard module 20 can be mounted in two different configurations. This feature allows the user the freedom to decide which position suits his needs best. An innovation of the invention is that the portable computer 10 fits into a “6U” bay in an industry-standard nineteen inch rack-mount cabinet. When the monitor/keyboard module 20 is attached to the CPU module 100 in the direction shown in FIG. 6C, the monitor 21, keyboard 22, and computer data storage devices 140 are easily assessable from the front side of the rack-mount cabinet. For clarity, recessed slots 611 are used to position the monitor/keyboard module 20 on CPU module 30 when the portable computer 10 is to be used on the desktop or rack-mounted, and slots 610 are used to position the monitor/keyboard module 20 on CPU module 30 for desktop use or for easy transport of the portable computer 10. This invention presents a unique solution to a longfelt need in that there are at present no computer servers or workstations that can be used on the desktop and then rack-mounted and then transported with ease on today's airlines.

It is to be understood that the present invention is not limited to the embodiments described above, but encompasses any and all embodiments within the scope of the following claims.

I claim:

1.) A portable computer, comprising:
a.) a monitor/keyboard module having a base, a detachable keyboard with touchpad mouse, and a monitor pivotally attached to the base such that the monitor can be rotated between its compact position in which it covers the keyboard to any viewing angle less than or equal to 180 degrees;
b.) a CPU module having a housing which has a handle and which encloses the main circuit board, central processing unit, system memory, a plurality of computer expansion cards (e.g., video controller card, a network interface card, modem card, SCSI and/or IDE controller cards), a power supply, a removable hard drive bay, and a plurality of bays for mounting standard commercial off-the-shelf computer data storage drives; and
c.) wherein said monitor/keyboard module is removably attached to said CPU module by means of tabs which extend rearwardly from said base and engage slots located on one side panel of said CPU module, and is secured by thumb screws located at the front corners of said base which engage threaded holes located on the aforementioned side panel of said CPU module.

2.) The portable computer according to claim 1, wherein the base of said monitor/keyboard module further comprises an AC adapter which has a cable for connection to said monitor and a receptacle for attachment of a power cord.

3.) The portable computer according to claim 1, wherein the base of said monitor/keyboard module further comprises a disk drive storage compartment for housing a disk drive, and a disk drive mounted in this disk drive storage compartment.

4.) The portable computer according to claim 1, wherein the base of said monitor/keyboard module further comprises:
a.) a keyboard compartment defined by elevated side walls, an inner divider wall which runs parallel to the bottom wall, a central retaining tab which sticks out perpendicular to the inner divider wall, and a pair of front keyboard retaining tabs; and
b.) a user assessable cable storage compartment defined to the rear of said keyboard compartment and having a pivotally mounted cover with a depending flange which releasably engages the central retaining tab to retain the cover in a closed position and a lip and tab overlaying said keyboard compartment for retaining the keyboard in said keyboard compartment.

5.) The portable computer according to claim 4, wherein a keyboard with touchpad mouse can be removed from and then reinstalled in said keyboard compartment so that the user can position the keyboard with touchpad in any desired way.

6.) The portable computer according to claim 4, wherein said cable storage compartment has sufficient room to store an AC adapter cable, a video cable for connecting said monitor to said video controller card inside said CPU module, a power cord for connecting the AC adapter to an electrical outlet, and a power cord for connecting said power supply to an electrical outlet.

7.) The portable computer according to claim 1, wherein said base is made from a plastic material.

8.) The portable computer according to claim 1, wherein said base is made from a metal material.

9.) The portable computer according to claim 1, wherein said monitor is a thin, flat monitor.

10.) The portable computer according to claim 1, wherein said monitor/keyboard module can be ported to and used by any other CPU module that requires a similar monitor, keyboard, and mouse.

11.) The portable computer according to claim 1, wherein said CPU module can be used with any standard computer monitor, keyboard, and mouse.

12.) The portable computer according to claim 1, wherein said monitor/keyboard module can be mounted on said CPU module in two discrete configurations.

13.) The portable computer according to claim 10, wherein said monitor/keyboard module is attached to said CPU module such that the portable computer fits into a “6U” bay in an industry-standard nineteen inch rack-mount cabinet so that said monitor, keyboard and touchpad mouse, and data storage drives are all easily assessable from the front side of the rack-mount cabinet.

14.) The portable computer according to claim 1, wherein said CPU module fits into most overhead compartments on today's major airlines.

15.) The portable computer according to claim 1, wherein said monitor/keyboard module fits into most overhead compartments on today's major airlines.

16.) The portable computer according to claim 1, wherein said monitor/keyboard module attached to said CPU module can be compactly stored for transport, e.g., in knapsack or other carry-on luggage, such that the combined modules can fit into most overhead compartments on today's major airlines.

17.) The portable computer according to claim 1, wherein said CPU module has a removable side panel which allows for easy maintenance and replacement of all computer components internal to said CPU module.

18.) The portable computer according to claim 1, wherein said CPU module houses a dual track system which allows said portable computer to be compact yet able to provide for the uncomplicated insertion and removal of a plurality of standard commercial off-the-shelf computer data storage devices.

19.) The portable computer according to claim 1, wherein said CPU module has a plurality of holes placed:
a.) on the side panel which houses said handle, closest to where the cpu is connected to the main circuit board;
b.) on the side panel which opposes said handle panel; and
c.) on the decorative unshaped brackets which cover the faces of the data storage devices secured within said dual track system.

20.) The portable computer according to claim 19, wherein the following fans are strategically placed opposing said holes:
a.) an intake fan is housed in said case and opposes said holes defined in claim 18a;
b.) an exhaust fan is housed in said case and opposes said holes defined in claim 18b; and
c.) an exhaust fan is housed in said case and oppose said holes defined in claim 18c.

21.) The portable computer according to claim 1, wherein said CPU module houses a removable hard drive tray which is accessible from the side of said CPU module opposing the dual track system and holds either two common 2.5″ notebook hard drives or one common 3.5″ hard drive.

22.) The portable computer according to claim 1, wherein power and data communications cables can be removably attached to a connector panel located on one side of said CPU module so that common computer data storage devices may be connected and disconnected exteriorly to said CPU module.

23.) The portable computer according to claim 1, wherein said monitor/keyboard module further comprises a lock mechanism pivotally attached to said base and releasably attachable to said monitor for locking said monitor in a compact position for storage, transport, security, and privacy.

24.) A monitor/keyboard module comprising:
a.) a base;
b.) a keyboard removably attached to the base; and
c.) a monitor pivotally attached to the base such that the monitor can be rotated between its compact position in which it covers the keyboard to any viewing angle less than or equal to 180 degrees.

25.) The monitor/keyboard module according to claim 24, further comprising an AC adapter having a receptacle for attachment of a power cord and a cable for connection to said monitor which can be retracted within said base for storage and transport of said monitor/keyboard module.

26.) The monitor/keyboard module according to claim 24, further comprising a disk drive mounted in said base.

27.) The monitor/keyboard module according to claim 24, wherein said base further comprises:
a.) a keyboard compartment defined by elevated side walls, an inner divider wall which runs parallel to the bottom wall, a central retaining tab which sticks out perpendicular to the inner divider wall, and a pair of front keyboard retaining tabs; and
b.) a user assessable cable storage compartment defined to the rear of said keyboard compartment and having a pivotally mounted cover with a depending flange which releasably engages the central retaining tab to retain the cover in a closed position and a lip and tab overlaying said keyboard compartment for retaining the keyboard in said keyboard compartment.

28.) The monitor/keyboard module according to claim 24, wherein said base further comprises a lock mechanism pivotally attached to said base and releasably attachable to said monitor for locking said monitor in a compact position for storage, transport, security, and privacy.

29.) The monitor/keyboard module according to claim 24, further comprising means for removably attaching said base to a CPU module.
